(19) United States
(12) Patent Application Publication
(10) Pub. No.: US 2025/0244407 A1
(43) Pub. Date: Jul. 31, 2025

(54) REMOTE LINE MONITORING SYSTEM AND METHOD

(71) Applicant: Preformed Line Products Company, Cleveland, OH (US)

(72) Inventors: Jean-Philippe Houle-Paradis, Montreal (CA); Elhacene Matene, Sainte Julie (CA); Pedro Henrique Correa Rocha, Montréal (CA)

(21) Appl. No.: 19/041,395

(22) Filed: Jan. 30, 2025

Related U.S. Application Data
(60) Provisional application No. 63/626,825, filed on Jan. 30, 2024.

(51) Int. Cl. G01R 31/58; G01D 21/02; G01K 1/024; G01L 5/04; G01W 1/04

(52) U.S. Cl. CPC G01R 31/58; G01D 21/02; G01K 1/024; G01L 5/047; G01W 1/04

(57) ABSTRACT

A line monitoring system includes a plurality of sensor nodes fixed along at least one line. Each of the sensor nodes includes an instrument that generates sensor data indicating a motion, rotation, position, temperature, or deformation of the line, and includes a transceiver that transmits the sensor data from the instrument. The system also includes a remote computer that indicates the sensor data to a user, where the sensor data from each of the sensor nodes is synchronized.

### CROSS REFERENCE TO RELATED APPLICATIONS

The application claims priority to and the benefit of U.S. Provisional Patent Application No. 63/626,825, filed on Jan. 30, 2024, entitled “Line Monitoring and Remote Measurement System and Method”, which we incorporate by reference in its entirety.

### BACKGROUND

Monitoring electrical power lines and other overhead cables is critical to ensuring the reliability, safety, and efficiency of power distribution systems. Power lines are exposed to a variety of environmental and operational factors, including various weather conditions, physical wear, and potential interference from vegetation or wildlife. Weather conditions affecting transmission lines include factors such as temperature, humidity, and wind, which may compound in degrading transmission line integrity. These factors may cause outages, equipment damage, or even hazardous conditions if not addressed promptly.

Traditional methods for monitoring power lines often rely on periodic inspections performed by maintenance crews. Such manual inspections are labor-intensive, time-consuming, and prone to human error.

Recent advancements in technology have enabled the development of systems that utilize remote sensing, automated data analysis, and real-time communication to address these challenges. By leveraging tools such as aerial drones, machine learning algorithms, and remote sensing devices, known monitoring systems may provide comprehensive, accurate, and timely insights into the condition of electrical power lines and overhead cables as compared to manual inspections. However, despite these advancements, existing solutions often face challenges related to scalability, and integration with legacy infrastructure.

### BRIEF DESCRIPTION

According to one aspect, a line monitoring system includes a plurality of sensor nodes fixed along at least one line. Each of the sensor nodes includes an instrument that generates sensor data indicating a motion, rotation, position, temperature, or deformation of the line, and includes a transceiver that transmits the sensor data from the instrument. The system also includes a remote computer that indicates the sensor data to a user, where the sensor data from each of the sensor nodes is synchronized.

According to another aspect, a line monitoring system includes a sensor node that is fixed to a line. The sensor node includes an instrument that generates sensor data indicating a condition of the line, and a transceiver that transmits the sensor data from the instrument. The line monitoring system also includes a tower hub that is fixed to a tower supporting the line. The tower hub includes a data gateway that receives the sensor data from the transceiver, and transmits the sensor data. The line monitoring system also includes a remote computer that receives the sensor data from the data gateway, and indicates the sensor data to a user.

According to another aspect, a method of monitoring at least one overhead transmission line in a distribution system includes fixing at least one sensor node to a span of the at least one overhead transmission line that extends between two transmission towers. Each of the at least one sensor node includes an accelerometer that detects a motion associated with the at least one overhead transmission line, and generates sensor data that indicates the motion. The method also includes determining a bending strain, an antinode amplitude, a damping efficiency, or a galloping amplitude of the at least one overhead transmission line based on the sensor data, and comparing the determination to an associated predetermined threshold using a processor. The method also includes indicating the sensor data at a remote computer based on the comparison between the determination and the associated predetermined threshold.

The innovation described herein describes a system and method for line management that offers robust, adaptable, and efficient automated monitoring capabilities. In addition to other described features, functions, and benefits, the line monitoring system described herein, employed on a power distribution system, enables remotely detecting, analyzing, alerting, and managing transmission line conditions.

### BRIEF DESCRIPTION OF THE DRAWINGS

FIG. 1 is a diagram of an example line monitoring system, in accordance with aspects of the innovation.

FIG. 2 is a diagram of a tower hub included in the line monitoring system of FIG. 1.

FIG. 3 is a diagram of a sensor node included in the line monitoring system of FIG. 1.

FIG. 4 is a diagram of a server and associated operating environment included in the line monitoring system of FIG. 1.

FIG. 5 is a partial, enlarged front view of the line monitoring system of FIG. 1, including a first sensor configuration according to an exemplary embodiment.

FIG. 6 is a partial, enlarged front view of the line monitoring system of FIG. 1, including a second sensor configuration according to another exemplary embodiment.

FIG. 7 is a partial, enlarged front view of the line monitoring system of FIG. 1, including a third sensor configuration according to another exemplary embodiment.

FIG. 8 is a partial, enlarged top perspective view of the line monitoring system of FIG. 1, including a fourth sensor configuration according to another exemplary embodiment.

FIG. 9 is a perspective view of the tower hub included in the line monitoring system of FIG. 1.

FIG. 10 is a perspective view of the sensor node included in the line monitoring system of FIG. 1.

FIG. 11 is an example process flow for the line monitoring system of FIG. 1.

### DETAILED DESCRIPTION

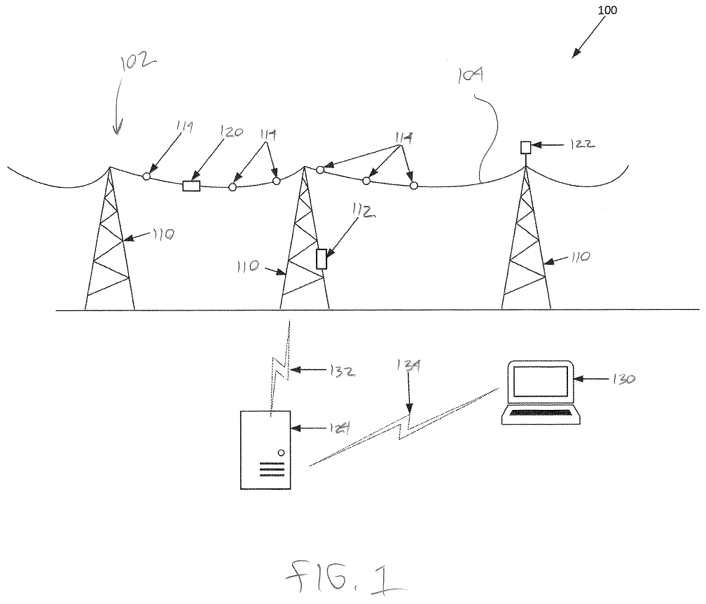

It should, of course, be understood that the description and drawings herein are merely illustrative and that various modifications and changes may be made in the structures disclosed without departing from spirit and scope the present disclosure. Referring now to the drawings, wherein like numerals refer to like parts throughout the several views, in accordance with an aspect of the innovation, FIG. 1 depicts a line monitoring system 100 that performs line monitoring and remote measurement along a distribution system 102. The distribution system 102 includes a transmission line 104 supported by a plurality of transmission towers 110. While, as depicted, the transmission line 104 is a power line that transmits electrical power across the distribution system 102, the transmission line 104 may additionally or alternatively include a telephone, optical fiber, cable television or other types of line, cable, or wire commonly used to transmit power or data signals over distances.

As depicted in FIG. 1, a tower hub 112 is removably fixed to a transmission tower 110 and configured to communicate with a plurality of sensor nodes 114, signal amplifiers 120, a weather station 122, a server 124, and a remote computer 130. The tower hub 112 may be in communication with a remote client device, such as the server 124 or the remote computer 130 via a distributed network, such as, for example and without limitation, the Internet. In this regard, the tower hub 112 communicates sensor data or signals with the server 124 over the network via a first communication link 132, the server 124 communicates data or signals with the remote computer 130 via a second communication link 134, and the remote computer 130 indicates the sensor data to a user. The first communication link 132 and the second communication link 134 may respectively be formed from any suitable communications channel for sending and receiving data or signals over the network, to the server 124 and the remote computer 130, including, for example and without limitation wireless communications, such as Bluetooth, WiMax, 802.11a, 802.11b, 802.11g, 802.11(x), 3G, 4G, 5G cellular communication systems, a proprietary communications network, infrared, optical, the public switched telephone network, or any suitable wireless data transmission system, or wired communications.

With continued reference to FIG. 1, the sensor nodes 114 are removably coupled to the transmission line 104. More specifically, the sensor nodes 114 are fixed along spans of the transmission line 104, in a longitudinal direction of the transmission line 104, between consecutive pairs of the transmission towers 110. The sensor nodes 114 are each in communication with the tower hub 112 via a suitable communications channel, including, for example and without limitation, wireless communications, such as Bluetooth, WiMax, 802.11a, 802.11b, 802.11g, 802.11(x), 3G, 4G, 5G cellular communication systems, a proprietary communications network, infrared, optical, RF, or any suitable wireless data transmission system. In some embodiments, the sensor nodes 114 may communicate with the signal amplifiers 120 to allow for sensor nodes 114 to transmit data to the tower hub 112 over increased distances from their respective attachment points on the transmission line 104.

As described in greater detail below, the sensor nodes 114 may be equipped with a variety of sensor components and embody a variety of sensor types to capture a variety of measurements of the transmission line 104 such as acceleration, strain, displacement, and temperature. The sensor nodes 114 may communicate sensor data to the tower hub 112, optionally via the signal amplifier 120. In this regard, the signal amplifier 120 is configured to extend a range of transmissions by the sensor nodes 114 transmitting sensor data to the tower hub 112, the sensor data indicating measurements associated with the transmission line 104.

In an embodiment, the sensor nodes 114 intermittently activate and perform measurements via the sensor components. Such intermittent activation may be in accordance with a command from the tower hub 112, in response to a triggering event such as a preset time interval trigger, an acceleration threshold trigger, a relative displacement threshold trigger, a strain threshold trigger, an environmental trigger, or the like.

The pre-set time trigger may be configured by the tower hub 112 or at least one of the sensor nodes 114. The acceleration threshold trigger, the relative displacement threshold trigger, the environmental trigger, or the strain threshold trigger may additionally or alternatively be determined by at least one of the sensor nodes 114. In still other embodiments, one or more of the triggers may be activated via the weather station 122. In one example embodiment, when a trigger condition occurs, at least one of the sensor nodes 114 may transition from an inactive or hibernation mode to an active mode, and communicate the activation to the tower hub 112.

With continued reference to FIG. 1, the signal amplifier 120 may receive and amplify radiofrequency (RF) signals sent from the sensor nodes 114, and transmit the RF signals to the tower hub 112. In some embodiments, the signal amplifier 120 includes a power unit having a battery, a transmission line tap, or energy harvesting component such as a solar or wind generator. The signal amplifier 120 may also include an RF transceiver, one or more RF antennae, and an RF signal repeater that communicate the sensor data from the sensor nodes 114 as signal data to various components of the line monitoring system 100, including the tower hub 112, the server 124 and the remote computer 130. In other embodiments, the signal amplifier 120 may include other components to communicate with other devices, e.g., the tower hub 112, server 124, etc., via one or more communications channels, to process signals, to analyze signals, or the like.

The weather station 122 may be configured to measure and report various weather conditions, measurements, and the like, to the tower hub 112 via any suitable communications channel, e.g., RF communications, direct wired connection, or other suitable wireless communications methods or channels. Various weather conditions, measurements, and the like made by the weather station 122 may include, for example and without limitation, local temperature, wind speed, wind direction, humidity, atmospheric pressure, and the like. While, as depicted, the weather station 122 is a single weather station mounted at a top portion of one of the transmission towers 110, the weather station 122 may additionally or alternatively include a plurality of sensor modules mounted on the various portions of the line monitoring system 100 and power distribution system 102, including the tower hub 112, where the sensor modules measure the various weather conditions, then generate and transmit associated sensor data through the tower hub 112 or the signal amplifier 120 without departing from the scope of the subject disclosure.

In some embodiments, such measurements are communicated from the weather station 122 to the tower hub 112 continuously, at predetermined intervals, in response to triggering conditions (e.g., wind speed threshold, temperature threshold, atmospheric pressure threshold, humidity level, etc.), or the like. In this manner, the weather station 122 generates sensor data indicating environmental conditions of the transmission line 104, and the tower hub 112 transmits the sensor data from the weather station 122 to the remote computer 130.

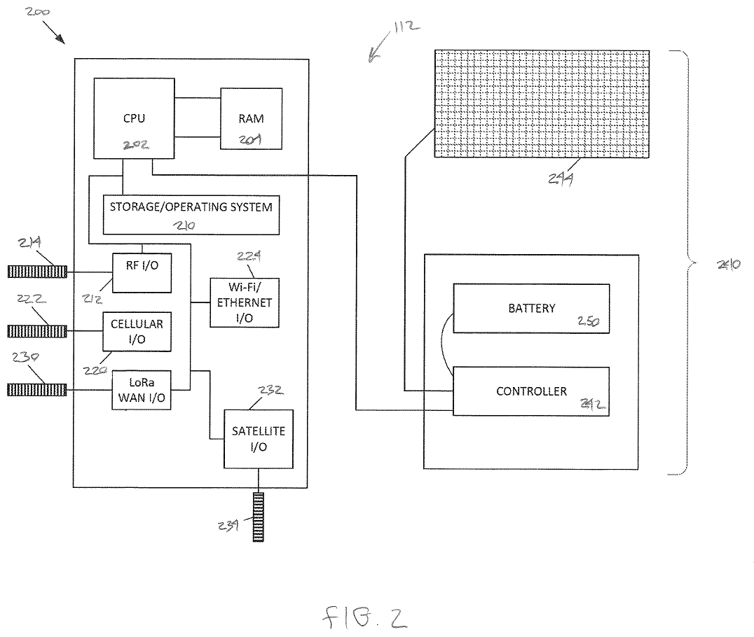

FIG. 2 depicts a diagram of an operating environment 200 of the tower hub 112, which is capable of implementing the methods set forth herein. The tower hub 112 includes a processor 202 and a random access memory (RAM) 204, which perform the exemplary methods by execution of processing instructions that are stored in a memory 210 connected to the processor 202, as well as controlling the overall operations of the tower hub 112. The various components of the tower hub 112 may be connected by a control bus. The memory 210 is capable of implementation on components of the tower hub 112, e.g., stored in the RAM 204, i.e., on hard drives, virtual drives, or the like, or on remote memory accessible to the tower hub 112.

While, as depicted in FIG. 1, the tower hub 112 is fixed to one of the transmission towers 110 as a single device, the tower hub 112 may alternatively embody a plurality of devices positioned on the distribution system 102, including the transmission towers 110. In this regard, for example, the tower hub 112 may additionally or alternatively include a cloud-based computing platform that provides a distributed processing system. Furthermore, while the line monitoring system 100 is depicted as including the tower hub 112 on one of the transmission towers 110, the line monitoring system 100 may additionally or alternatively include a plurality of tower hubs similar to the tower hub 112, where each of the tower hubs is respectively mounted on one of the transmission towers 110, and processes and communicates the sensor data from the sensor nodes 114 without departing from the scope of the subject disclosure.

Referring back to FIG. 2, the memory 210 is representative of any organized collections of data used for one or more purposes. In embodiments, the memory 210 stores an operating system or one or more programs or instructions executable by the processor 202 to perform various components of the methods described herein. Implementation of the memory 210 is capable of occurring on any mass storage device(s), for example, magnetic storage drives, a hard disk drive, optical storage devices, flash memory devices, or a suitable combination thereof.

The memory 210 may be implemented as a component of the tower hub 112, e.g., resident in the RAM 204, or the like. In an embodiment, the memory 210 may include, for example and without limitation, data corresponding to measurements received from the sensor nodes 114, weather measurements received from the weather station 122, instructions received from the remote server 124 or the remote computer 130, instructions for processing measurement data, processed measurement data, communications protocols, and the like.

With continued reference to FIG. 2, the tower hub 112 includes a plurality of input/output (I/O) interface devices for communicating with external devices. In this regard, the tower hub 112 includes an RF I/O interface 212 that is an RF transceiver configured to communicate with the sensor nodes 114 via, for example, an encrypted local private network. The tower hub 112 also includes an RF antenna 214 operatively coupled to the RF I/O interface 212.

The tower hub 112 also includes a cellular I/O interface 220 that is a cellular modem configured to communicate with the server 124 or the remote computer 130 via, for example, a proprietary or commercial cellular telephone network. The tower hub 112 includes a cellular antenna 222 operatively coupled to the cellular I/O interface 220. In some embodiments, the cellular I/O interface 220 may be configured to communicate via any suitable cellular communications protocols or networks, including, for example and without limitation, 3G, 4G, 5G, 6G, mmWave, etc.

The tower hub 112 also includes a Wi-Fi I/O interface 224 that is a Wi-Fi transceiver such as an IEEE802.11 (x) interface, or an Ethernet interface, and configured to communicate with the server 124 or the remote computer 130 via a computer network. The Wi-Fi I/O interface 224 may be configured as a LoRa WAN interface or transceiver that supports an Internet-of-Things (IoT) communications protocol, and communicates with the server 124, the remote computer 130, or other devices via a computer network such as the Internet. In this regard, the tower hub 112 may further include a LoRaWAN antenna 230 operatively coupled to the Wi-Fi I/O interface 224.

The tower hub 112 also includes a satellite I/O interface 232 that is a satellite transceiver configured to communicate with the server 124 or the remote computer 130 via, for example, a satellite telecommunications network or wide area network. The tower hub 112 includes a satellite antenna 234 operatively coupled to the satellite I/O interface 232.

With continued reference to FIG. 2, the tower hub 112 further includes a power unit 240 operatively coupled to various components associated with the tower hub 112 to provide power to the various components. As depicted, the power unit 240 includes a power controller 242, an energy harvesting device 244, and a battery 250.

In such embodiments, the power controller 242 may include one or more components configured to control power supplied to the processor 202 and other components of the tower hub 112, a rate of battery charging, battery management, control of the energy harvesting device 244, and the like. Accordingly, the power controller 242 may include a processor in communication with a memory configured to control the aforementioned aspects.

The power controller 242 may further include communications components configured to communicate information such as battery status, energy operations, etc., to the processor 202 or other suitable component of the tower hub 112. The power controller 242 may be further configured to control when to charge, discharge, or otherwise manage the battery 250.

In some embodiments, the energy harvesting device 244 may be optional, such that the tower hub 112 operates only on the stored energy in the battery 250. For example, in such an embodiment, the power unit 240 may only include the power controller 242 and the battery 250. In implementations utilizing the energy harvesting device 244, the power controller 242 may be configured to regulate the charging of the battery 250 using power generated, collected, or otherwise harvested by the energy harvesting device 244.

In this regard, the energy harvesting device 244 may include energy generation devices that capture energy from an environment of the line monitoring system 100. Such energy generation devices may include, for example and without limitation, a solar panel or array or a wind turbine. The energy harvesting device 244 may also include an apparatus that captures energy from the transmission line 104, and as piezo-harvesters or a tap into the transmission line 104 (e.g., an inductive generation device). The energy harvesting device 244 may also include a direct power line such as a separate power transmission line dedicated to powering the tower hub 112, or the like. The energy harvesting device 244 may additionally or alternatively include a current transformer, an inductive power harvester, and a capacitive coupler that draw electricity from the transmission line 104.

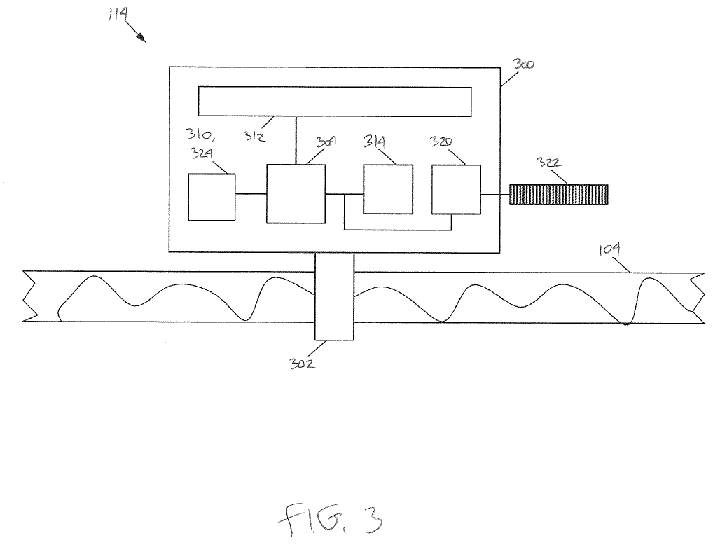

FIG. 3 depicts a diagram of one of the sensor nodes 114 in accordance with some embodiments. As shown in FIG. 3, the sensor node 114 includes a housing 300 that is a sensor node body in which one or more components are located. The housing 300 includes a coupler 302 configured to couple the sensor node 114 to the transmission line 104. The housing 300 may be constructed of a suitable rigid material such as metal, metal-alloy, high density polymer, composite materials, and the like. In one embodiment, the housing 300 is a machined aluminum casing, substantially cylindrical in shape, with the coupler 302 perpendicularly extending from a long axis of the cylinder. In some embodiments, the coupler 302 may include some attachment mechanism configured to secure the sensor node 114 to the transmission line 104. In some examples, the coupler 302 may include a clamp, secured via bolts, locks, or other captive components.

The sensor node 114 also includes one or more internal components configured to perform a variety of functions. As depicted, the sensor node 114 includes a sensor controller 304, e.g., a processor and memory, SoC, CPU-RAM, etc., one or more sensing instruments 310 (i.e., sensors), a power unit 312, an internal temperature probe 314, an RF transceiver 320, and an RF antenna 322.

With continued reference to FIG. 3, in some embodiments, the one or more sensing instruments 310 includes a main instrument 324, including, for example and without limitation, an accelerometer, an inertial measurement unit, a strain sensor, a displacement sensor, etc. In some embodiments, when the sensor node 114 is implemented as an acceleration sensing node, the main instrument 324 may correspond to a triaxial accelerometer. As described in greater detail below, each of the one or more sensing instruments 310 and the main instrument 324 generate sensor data indicating a condition of the transmission line 104. In an embodiment, the condition of the transmission line 104 is a motion, rotation, position, temperature, or deformation of the transmission line 104.

When the sensor node 114 is implemented as a relative displacement sensing node, the main instrument 324 may be implemented using a strain-instrumented beam coupled with a Wheatstone bridge signal conditioning module. When the sensor node 114 is implemented as a strain sensing node, the main instrument 324 may include the same signal conditioning module(s) as those of the displacement sensing node, that may be configured to measure strain from load cells or other similar devices. It will be appreciated that the line monitoring system 100 may be implemented with a variety of the same or different types of sensor nodes 114, e.g., one or more acceleration sensing nodes, one or more displacement sensing nodes, one or more strain sensing nodes, etc.

The power unit 312 may be implemented as one or more batteries, super-capacitors, an energy management system, energy harvesting system(s), etc. In an embodiment, the power unit 312 includes a battery that stores energy on an electrical circuit connected to the one or more instruments 310, the main instrument 324, or the RF transceiver 320. The power unit 312 may further include an energy generation device that is a solar panel or a wind turbine operatively connected to the electrical circuit. The power unit 312 may also include an energy harvesting device that draws electricity from the transmission line 104 to the electrical circuit. In this regard, the power unit 312 of the sensor node 114 may include similar features and function in a similar manner as the power unit 240 of the tower hub 112, further description of which is omitted for the sake of brevity.

With continued reference to FIG. 3, the RF transceiver 320 transmits the sensor data generated by the one or more instruments 310 or by the main instrument 324 to the signal amplifier 120, the tower hub 112, the server 124, or the remote computer 130. The RF antenna 322 operatively coupled to the RF transceiver 320 may be implemented as an omnidirectional antenna that wirelessly transmits the sensor data from the one or more instruments 310 or the main instrument 324. The RF antenna 322 may have a predetermined range to enable bi-directional communication with the tower hub 112 RF I/O interface 212 or the signal amplifiers 120.

The internal temperature probe 314 is a thermometer in thermal contact with the transmission line 104, and measures a temperature of the transmission line 104 at a conductor of the transmission line 104. The internal temperature probe 314 generates conductor temperature data indicating the conductor temperature of the transmission line 104 as the sensor data. The conductor temperature indicated by the internal temperature probe 314 may correspond to an ampacity, a dynamic line rating, a rate of thermal expansion, an electrical loading, thermal cycling, a hot spot detection, and excess resistive losses in the transmission line 104. As such, the tower hub 112, the server 124, or the remote computer 130 may determine one or more of these aspects or conditions of the transmission line 104 based on sensor data generated at the internal temperature probe 314.

The determined conductor temperature may be associated with a predetermined threshold corresponding to the ampacity, the dynamic line rating, the rate of thermal expansion, the electrical loading, thermal cycling, hot spot detection, and excess resistive losses in the transmission line 104. As such, the tower hub 112, the server 124, or the remote computer 130 may automatically trigger and generate a notification at the remote computer 130 based on the determined conductor temperature of the transmission line 104 and the predetermined threshold. In this manner, the line monitoring system 100 may function as a remote alarm system that alerts a user at the remote computer 130 that at least one of the ampacity, the dynamic line rating, the thermal expansion, the electrical loading, thermal cycling, hot spot detection, and excess resistive losses in the transmission line 104 exceeds or otherwise fails a predetermined threshold.

The one or more instruments 310 or the main instrument 324 may also include a thermometer that generates the sensor data indicating an air temperature around the transmission line 104. Further, the remote computer 130 indicates the conductor temperature, the air temperature, or an amount of thermal cycling in the transmission line 104 based on the sensor data. With this construction, the remote computer 130 indicates the conductor temperature, the air temperature, or an amount of thermal cycling in the transmission line 104 based on the sensor data. As such, a user at the remote computer 130 may determine an amount of thermal cycling in the transmission line 104 caused by environmental conditions.

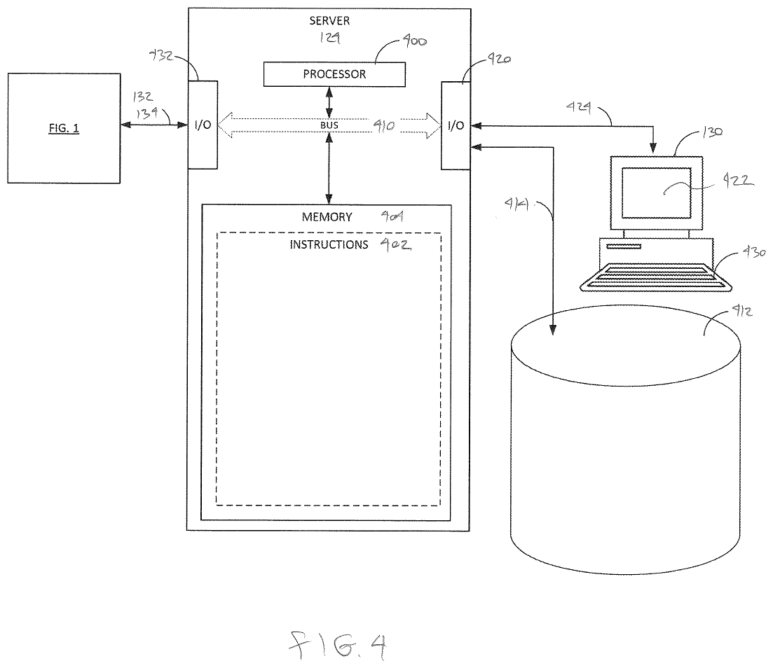

FIG. 4 depicts a diagram of the server 124. As shown in FIG. 4, the server 124, which is capable of implementing the methods set forth herein, includes a processor 400, which performs the exemplary method by execution of processing instructions 402 that are stored in a memory 404 connected to the processor 400, as well as controlling the overall operations of the server 124. The various components of the server 124 may be connected by a data/control bus 410. The processor 400 of the server 124 may be in communication with an associated database 412 via a suitable communications link 414. The suitable communications link 414 may include, for example, a switched telephone network, a wireless radio communications network, infrared, optical, or other suitable wired or wireless data communications. The database 412 is capable of implementation on components of the server 124, e.g., stored in local memory 404, i.e., on hard drives, virtual drives, or the like, or on remote memory accessible to the server 124. While the server 124 is depicted in FIGS. 1 and 4 as a single device, the server 124 may be representative of a cloud-based computing, i.e., distributed processing system, and the illustration of the server 124 as a single device is intended solely as a non-limiting illustrative example. As such, the server 124 may additionally or alternatively include a plurality of devices that perform the described functions in the line monitoring system 100 without departing from the scope of the present disclosure.

With reference to FIG. 4, the associated database 412 is representative of any organized collections of data used for one or more purposes. Implementation of the associated database 412 may occur on any mass storage device(s) such as, for example, magnetic storage drives, hard disk drives, optical storage devices, flash memory devices, or a suitable combination thereof. The associated database 412 may be implemented as a component of the server 124, e.g., resident in the memory 404, or the like. In an embodiment, the associated database 412 may include, for example and without limitation, data corresponding to weather conditions, sensor node identification, sensor node position information, weather station position information, weather station identification information, communication protocols, processing formulae, transmission line information, trigger conditions, sensor node type information, reporting requirement information, temperature information, environmental information, etc. In other embodiments, the database 412 may further include, for example and without limitation, information about a user associated with the remote computer 130, e.g., preferences, reporting requirements, contact information, alert notification information, account information, geographical information, etc. While, in the depicted embodiment, the remote computer 130 is a desktop computer, the remote computer may additionally or alternatively include a variety of computing devices, including mobile devices or wearable devices operated by a user for interfacing and controlling the line monitoring system 100.

The server 124 may include one or more input/output (I/O) interface devices for communicating with devices external to the line monitoring system 100. In this regard, the server 124 includes a first I/O interface 420 that communicates with one or more display devices 422 via a communications link 424 for displaying information. The display device 422 includes a user input device 430, such as a keyboard or touch or writable screen, for inputting text, remote control with buttons, or a cursor control device, such as mouse, trackball, or the like, for communicating user input information and command selections to the processor 400. The server 124 includes a second I/O interface 432 that communicates with external devices such as the tower hub 112, the remote computer 130, and the like, via the first communication link 132 and the second communications link 134.

It will be appreciated that the server 124 illustrated in FIG. 4 is capable of implementation using a distributed computing environment, such as a computer network, which is representative of any distributed communications system capable of enabling the exchange of data between two or more electronic devices. It will be further appreciated that such a computer network includes, for example and without limitation, a virtual local area network, a wide area network, a personal area network, a local area network, the Internet, an intranet, or any suitable combination thereof. Accordingly, such a computer network includes physical layers and transport layers, as illustrated by various conventional data transport mechanisms, such as, for example and without limitation, Token-Ring, Ethernet, or other wireless or wire-based data communication mechanisms. Furthermore, while depicted in FIG. 4 as a networked set of components, the server 124 is capable of implementation on a stand-alone device adapted to interact with the tower hub 112, and the remote computer 130 described herein.

The server 124 may include one or more of a computer server, workstation, personal computer, cellular telephone, tablet computer, pager, combination thereof, or other computing device capable of executing instructions for performing the exemplary method. According to one example embodiment, the server 124 includes hardware, software, or any suitable combination thereof, configured to interact with an associated user, a networked device, networked storage, remote devices, or the like.

The memory 404 illustrated in FIG. 4 as a component of the server 124 may represent any type of non-transitory computer readable medium such as random access memory (RAM), read only memory (ROM), magnetic disk or tape, optical disk, flash memory, or holographic memory. In one embodiment, the memory 404 includes a combination of random access memory and read only memory. In some embodiments, the processor 400 and the memory 404 may be combined in a single chip. The first I/O interface 420 and the second I/O interface 432 respectively allow the server 124 to communicate with other devices via the first communication link 132 and the second communication link 134. Also, each of the first I/O interface 420 and the second I/O interface 432 may include a modulator/demodulator (MODEM). The memory 404 may store data processed in the method as well as the instructions for performing the exemplary method.

The processor 400 may be variously embodied, such as by a single core processor, a dual core processor or a multiple core processor, a digital processor and cooperating math coprocessor, a digital controller, or the like. The digital processor 400, in addition to controlling the operation of the server 124, executes the instructions 402 stored in the memory 404 for performing the method set forth hereinafter. As shown in FIG. 4, the memory 404 may store one or more instructions 402, which when executed by the processor 400, may cause the processor 400 to perform certain functions in the processing, analysis, and presentation of data received from the hub tower 112 relating to the transmission line 104. It will be appreciated that while not shown, the remote computer 130 may include similar components as that of the server 124, e.g., processor, memory, display, input/output devices, I/O interfaces, instructions, etc.

In accordance with one example implementation, and with reference to FIG. 3, the sensor node 114 may include a variety of different main instruments 324, enabling the collection of different measurements associated with the transmission line 104. For example, strain, acceleration, displacement, etc., sensor nodes 114 may be used, and appropriately affixed or secured to the transmission line 104. In such an implementation, one or more of the signal amplifiers 120 may be attached to the transmission line 104 to enable disparately distanced sensor nodes 114 to effectively communicate with the tower hub 112 affixed to one of the transmission towers 110. The weather station 122 may be affixed to one or more of the transmission towers 110 and configured to communicate with the tower hub 112, as discussed above.

With reference to FIG. 1, in varying embodiments, the line monitoring system 100 may be used with multiple trigger configuration options, such as a pre-set time interval trigger, an acceleration threshold trigger, a relative displacement trigger, a strain trigger, or an environmental trigger that cause the sensor nodes 114, the signal amplifiers 120, the tower hub 112, or the server 124 to generate a notification to the remote computer 130. In this manner, the line monitoring system 100 functions as a remote alarm system to the remote computer 130, and is configured to notify a user when a predetermined trigger is activated. The pre-set time trigger may be applied by the tower hub 112, and the remaining triggers may be applied at the sensor nodes 114 or the weather station 122.

When a trigger applied at the sensor nodes 114 or the weather station 122 occurs, the sensor node 114 or the weather station 122 may move from a hibernation idle mode to an active mode. The sensor node 114 or weather station 122 then transmits, e.g., via RF communication, a command or instruction to the tower hub 112 to initiate a data acquisition cycle. In this manner, the line monitoring system 100 may conserve power in operating the sensor nodes 114, the signal amplifiers 120, and the weather station 122 on the transmission lines 104.

With continued reference to FIG. 1, when the activation trigger occurs at the tower hub 112, i.e., the pre-set time interval trigger, the tower hub 112 is configured to broadcast, e.g., via RF communications, a reference clock to each of the sensor nodes 114 or the weather station 122 of the line monitoring system 100. Upon receipt of the reference clock, each of the sensor nodes 114 or weather station 122 of the line monitoring system 100 initiate data acquisition in accordance with a preset acquisition frequency. The acquired data (e.g., raw signal) is then communicated to the tower hub 112 via the local RF network, i.e., the RF I/O interface 212 receives the raw signal from each of the sensor nodes 114. In some instances, the raw signal is received from the signal amplifier(s) 120 from those sensor nodes 114 positioned beyond a corresponding effective RF transmission range. One or more time synchronization algorithms may be used on the sensor node signals, as will be appreciated.

After completing the data transfer, each sensor node 114 may return to its hibernation mode. At the tower hub 112, the raw time-domain data received from the sensor nodes 114 or the weather station 122 is saved on the memory 210 or communicated to the remote server 124 for storage in the database 412. In some embodiments, the raw data is sent to the remote server 124 using the cellular I/O interface 220.

The raw data may be processed by the processor 202 of the tower hub 112 or by the processor 400 of the server 124 for visualization. In some embodiments, the raw data may also be processed for data reduction on the tower hub 112 to enable transmission over the satellite I/O interface 232 using satellite telecommunications to the remote server 124.

Processing of the raw data for analysis may be performed using one or more open platforms, without recourse to numerical models. Mathematical functions available in open scientific literature related to the processing of the raw data may also be used.

With continued reference to FIG. 1, in varying embodiments contemplated herein, the sensor nodes 114 of the line monitoring system 100 may be installed at any location on the transmission line 104 to measure a specific quantity. The tower hub 112 may be installed at a location allowing it to be within RF range of all sensor nodes 114. The signal amplifier 120 may be used to extend the range.

It will be appreciated that some analysis may require sensor nodes 114 to be positioned at specific locations. For example, to measure a relative bending amplitude of the transmission line 104, the relative displacement sensor type of the sensor node 114 will be installed in the vicinity of cable support or suspension points where the transmission line 104 is supported on the transmission towers 110, since these locations will display a higher curvature value when the transmission line 104 is in motion. To measure antinode and node amplitudes of vibration, the mechanical power flow, and cable rotational and transversal movements along the transmission line 104, two or more acceleration sensing type sensor nodes 114 may be positioned close to each other. In this regard, flow of mechanical energy through a superposition of traveling waves, such as incident waves and reflected waves traveling in opposite directions along the transmission line 104, may be determined using the time-synced signal of accelerometers in the sensor nodes 114, the distance between each of the sensor nodes 114, and the wave velocity in the transmission line 104.

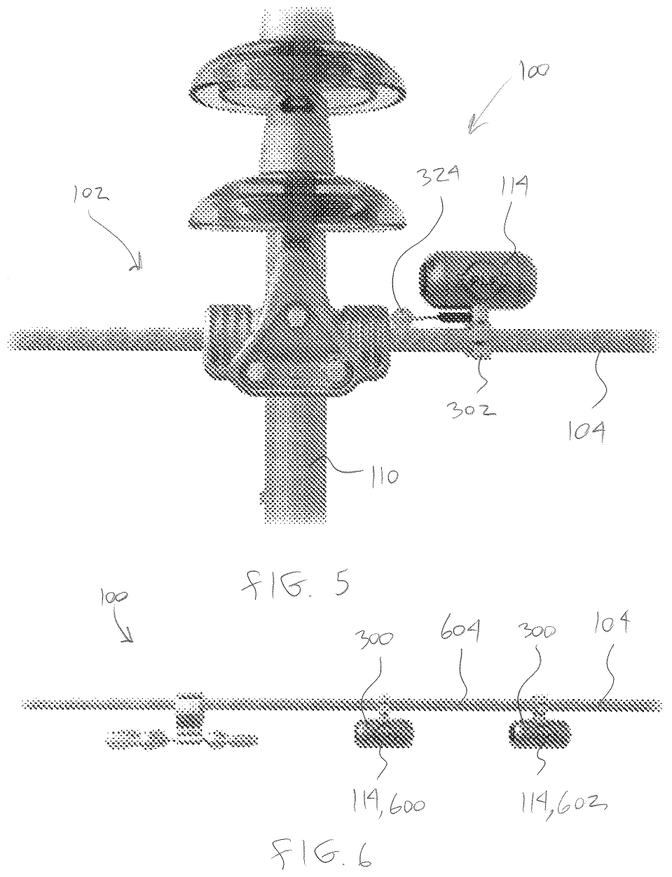

FIG. 5 depicts the sensor node 114 in a first sensor configuration, according to an exemplary embodiment of the line monitoring system 100. As depicted, the sensor node 114 is fixed to the transmission line 104 by the coupler 302, at the transmission tower 110. The main instrument 324 of the sensor node 114 includes a strain gauge fixed with the transmission line 104, at a location along the transmission line 104 where the transmission tower 110 supports the transmission line 104. The strain gauge included in the main instrument 324 measures a bending strain in the transmission line 104 when the transmission line 104 vibrates.

From the bending strain data generated by the sensor node 114 at the main instrument 324, an amplitude of aeolian vibration may be inferred using an established relationship between the bending strain and the actual vibration amplitude of the transmission line 104. In this regard, the sensor nodes 114, the tower hub 112, the server 124, or the remote computer 130 determine the amplitude of aeolian vibration in the transmission line 104, and the remote computer 130 indicates the amplitude of aeolian vibration to a user.

In this manner, the line monitoring system 100 performs the inverted bending amplitude method in determining the amplitude of aeolian vibration in the transmission line 104. In an embodiment, the amplitude of aeolian vibration in the transmission line 104 is associated with a predetermined trigger, and the sensor node 114 generates a notification to the remote computer 130 when a determined amplitude of the aeolian vibration in the transmission line 104 exceeds or otherwise fails a predetermined threshold value. As such, the remote computer 130 may be triggered to automatically generate a notification indicating the sensor data from the sensor nodes 114 when the condition of the line fails a predetermined threshold.

FIG. 6 depicts the sensor nodes 114 in a second sensor configuration, according to another exemplary embodiment of the line monitoring system 100. As depicted, the sensor nodes 114 include a first sensor node 600 and a second sensor node 602 fixed to the transmission line 104. More specifically, the transmission line 104 is a single line that spans two consecutive transmission towers 110. In this manner, the transmission line 104 forms a single, continuous, overhead span 604 extended between the two consecutive transmission towers 110 in the longitudinal direction of the transmission line 104. Furthermore, each of the first sensor node 600 and the second sensor node 602 are fixed along the same span 604 of the transmission line 104 extended between the two consecutive transmission towers 110 that support the transmission line 104.

The main instrument 324 in each of the first sensor node 600 and the second sensor node 602 is an accelerometer that generates the sensor data indicating motion of the transmission line 104 along the span 604, from a location inside the housing 300 or the first sensor node 600 and the second sensor node 602 respectively. In an embodiment, the accelerometer included in each of the first sensor node 600 and the second sensor node 602 is a triaxial accelerometer that detects motion in any radial direction of the transmission line 104 perpendicular to the longitudinal direction, and detects motion in the longitudinal direction along the transmission line 104.

With continued reference to FIG. 6, the first sensor node 600 and the second sensor node 602 are positioned proximal to each other on the transmission line 104 such that a flow of mechanical power, such as waves along the transmission line 104 in the radial direction or the longitudinal direction may be detected by both the first sensor node 600 and the second sensor node 602. In this manner, the accelerometers in the first sensor node 600 and the second sensor node 602 are spaced from each other along the transmission line 104 and respectively detect acceleration motion of the first sensor node 600 and the second sensor node 602 translated from the transmission line 104.

The first sensor node 600 and the second sensor node 602 generate acceleration data associated with the transmission line 104 as the sensor data, and transmit the sensor data to operatively connected elements of the line monitoring system 100. At least one of the sensor nodes 114, the signal amplifiers 120, the tower hub 112, the server 124, and the remote computer 130 process the sensor data generated at the first sensor node 600 and the second sensor node 602, and determine a damping value of the mechanical power flowing along the transmission line 104 based on the sensor data.

The remote computer 130 indicates a damping efficiency associated with the transmission line 104 based on the detected mechanical power flow and the determined damping value. In this manner, the line monitoring system 100 may determine an effectiveness of a mechanical damping system associated with the transmission line 104 or the transmission towers 110, and generate corresponding remote alarms to a user.

In an embodiment, the sensor nodes 114, the signal amplifiers 120, the tower hub 112, the server 124, or the remote computer 130 is set with a trigger associated with a predetermined threshold of damping. In such an embodiment, the sensor nodes 114, the signal amplifiers 120, the tower hub 112, the server 124, or the remote computer 130 may generate a notification at the remote computer 130 based on the determined damping value of the transmission line 104 compared to the predetermined threshold. In this manner, the line monitoring system 100 may generate remote alarms indicating effectiveness of a damping system in the distribution system 102, compared to a predetermined threshold.

In an embodiment, the sensor nodes 114, the signal amplifiers 120, the tower hub 112, the server 124, or the remote computer 130 performs the inverse standing wave ratio method using the acceleration data generated at the sensor nodes 114 to estimate an antinode amplitude of vibration of the transmission line 104. More specifically, the first sensor node 600 and the second sensor node 602 are fixed between two consecutive antinodes of the transmission line 104, where each of the first sensor node 600 and the second sensor node 602 generate the sensor data indicating motion of the transmission line 104. The sensor nodes 114, the signal amplifiers 120, the tower hub 112, the server 124, or the remote computer 130 calculate the antinode amplitude of vibration of the transmission line 104 based on the sensor data generated by the first sensor node 600 and the second sensor node 602.

In an embodiment, the first sensor node 600 and the second sensor node 602 generate the sensor data indicating aeolian vibration along the span 604 of the transmission line 104, and the remote computer 130 indicates the antinode amplitude of the transmission line 104 based on the sensor data indicating the aeolian vibration along the span 604. In a further embodiment, the sensor nodes 114, the signal amplifiers 120, the tower hub 112, the server 124, or the remote computer 130 may generate a notification at the remote computer 130 based on the determined antinode amplitude of vibration of the transmission line 104 compared to a predetermined threshold. In this manner, the line monitoring system 100 may generate remote alarms to a user indicating a standing wave intensity along the transmission line, compared to a predetermined threshold.

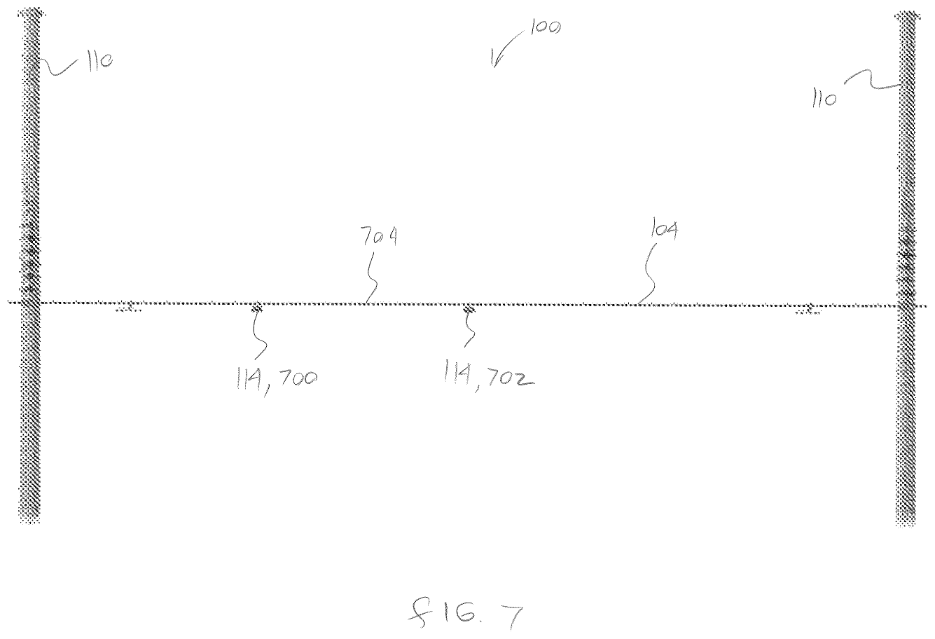

FIG. 7 depicts an embodiment where the sensor nodes 114 are positioned in a third sensor configuration on the transmission line 104, farther across a span between the transmission towers 110 as compared to the sensor nodes 114 depicted in FIG. 6. In this regard, the sensor nodes 114 include a first sensor node 700 and a second sensor node 702 spaced from each other about a quarter length of a span 704 of the transmission line 104.

More specifically, the second sensor node 702 is fixed along the transmission line 104 at a midpoint of the span 704 between the two consecutive transmission towers 110. The first sensor node 700 is fixed along the transmission line 104 at one of two quarter-points of the span 704 located between one of the transmission towers 110 and the second sensor node 702. The second sensor node 702 is fixed along the transmission line 104 at a location closer to the midpoint of the span 704 as compared to either of the two quarter-points, and the first sensor node 700 is fixed along the transmission line 104 at a location closer to the quarter-point as compared to the midpoint or any of the transmission towers 110.

With this construction, as compared to the sensor nodes 114 depicted in FIG. 6, the sensor nodes 114 depicted in FIG. 7 may measure relatively large, low frequency accelerations along the transmission line 104. In this manner, the sensor nodes 114 may measure a galloping amplitude along the transmission line 104 caused by wind or other environmental factors.

In an embodiment, the sensor nodes 114, the signal amplifiers 120, the tower hub 112, the server 124, or the remote computer 130 is set with a trigger associated with a predetermined threshold of galloping motion along the transmission line 104. In such an embodiment, the sensor nodes 114, the signal amplifiers 120, the tower hub 112, the server 124, or the remote computer 130 may generate a notification at the remote computer 130 based on the determined galloping amplitude of the transmission line 104 compared to the predetermined threshold. In this manner, the line monitoring system 100 may generate remote alarms indicating effects of weather conditions including wind in the distribution system 102, compared to a predetermined threshold.

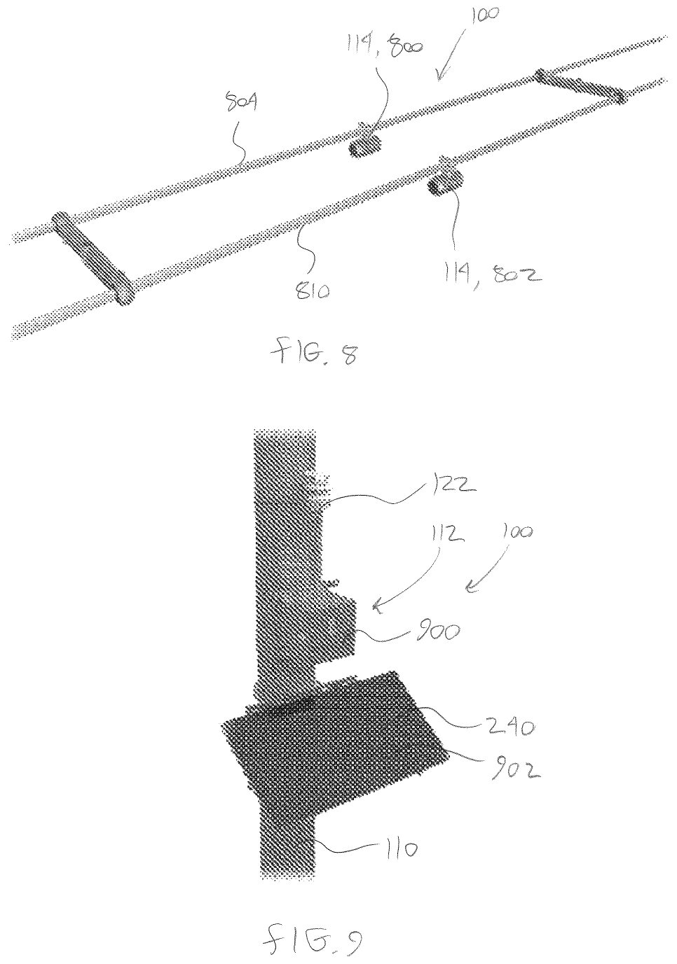

FIG. 8 depicts the sensor nodes 114 in a fourth sensor configuration, according to another exemplary embodiment of the line monitoring system 100. As depicted, the sensor nodes 114 include a first sensor node 800 and a second sensor node 802 respectively fixed to a first transmission line 804 and a second transmission line 810. The first transmission line 804 and the second transmission line 810 span a same set of transmission towers 110, and are offset from each other in the radial direction. As such, each of the first transmission line 804 and the second transmission line 810 are respectively supported between and span two consecutive transmission towers 110.

More specifically, the first sensor node 800 and the second sensor node 802 are respectively fixed at midpoints of the first transmission line 804 and the second transmission line 810 spanning the transmission towers, in the longitudinal direction between the transmission towers. Each of the first sensor node 800 and the second sensor node 802 includes an accelerometer in the corresponding main instrument 324, and measure span oscillation displacement traces in the transmission line 104.

With this construction, the first transmission line 804 and the second transmission line 810 may detect wake-induced oscillations in the first transmission line 804 and the second transmission line 810. In this regard, for example, when wind flows in the radial direction from the first transmission line 804 and across the second transmission line 810, the first sensor node 800 and the second sensor node 802 may detent consequential oscillations between the first transmission line 804 and the second transmission line 810.

Notably, such wake-induced oscillations may be largest at the midpoints of the first transmission line 804 and the second transmission line 810, where the first sensor node 800 and the second sensor node 802 are positioned. As such, the first sensor node 800 and the second sensor node 802 being positioned on the midpoints of the first transmission line 804 and the second transmission line 810 locates the corresponding accelerometers where the wake-induced oscillation is most detectable.

The sensor nodes 114, the signal amplifiers 120, the tower hub 112, the server 124, or the remote computer 130 may process the sensor data generated by the first sensor node 800 and the second sensor node 802 and determine a galloping motion in the first transmission line 804 or the second transmission line 810. The remote computer 130 indicates the galloping motion of the first transmission line 804 or the second line 810 based on detected motion at the first sensor node 800 or the second sensor node 802.

The weather station 122 is local to the first transmission line 804 and the second transmission line 810, where the weather station 122 generates environmental data indicating wind speed and direction at the first transmission line 804 and the second transmission line 810 as the sensor data. The remote computer 130 indicates the galloping motion of the first transmission line 804 or the second transmission line 810 based on the environmental data and the detected motion at the first sensor node 800 or the second sensor node 802.

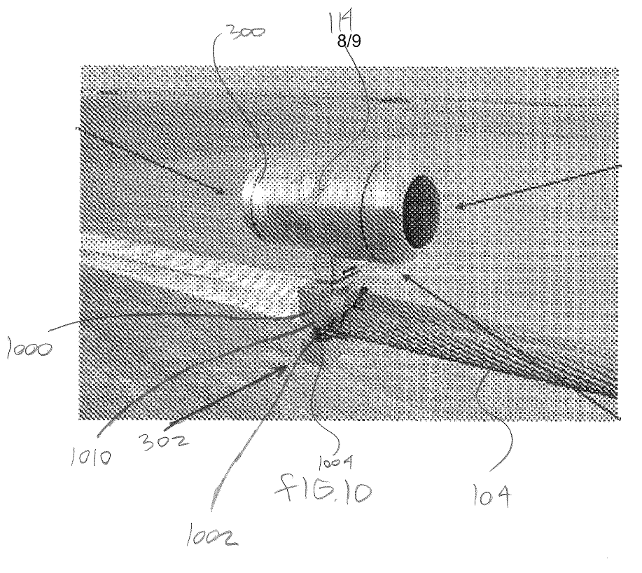

FIG. 9 depicts the tower hub 112 according to an exemplary embodiment. As shown in FIG. 9, the tower hub 112 includes the weather station 122, a data gateway 900, and the power unit 240.

The weather station 122 may include a variety of sensors for determining local environmental conditions. In this regard, the weather station 122 may include a thermometer that measures air temperature, a hygrometer that measures relative humidity, a barometer that measures atmospheric pressure, an anemometer that measures wind speed and may include a cup, vane, or ultrasonic design. The weather station 122 may additionally or alternatively include a wind vane that measures a wind direction, a rain gauge that measures precipitation, a pyranometer that measures sunlight intensity, and a snow sensor that measures snow depth and water content.

The data gateway 900 is operatively connected to the weather station 122 and the power unit 240, where the data gateway 900 communicates information between the tower hub 112 and other components of the line monitoring system 100, and receives operational electrical power from the power unit 240. More specifically, the battery 250 stores energy on an electrical circuit connected to the data gateway 900 and the weather station 122, and the power harvesting device 244 includes a power generation device that is a solar panel or a wind turbine operatively connected to the electrical circuit. In the depicted embodiment, the sensor nodes 114 transmit generated sensor data to the tower hub 112 via the signal amplifiers 120 and the data gateway 900.

As depicted in FIG. 1, the signal amplifier 120 is fixed to the transmission line 104 at a location between one of the sensor nodes 114 and the tower hub 112 in the longitudinal direction of the transmission line 104, where the RF transceiver wirelessly transmits the sensor data from the sensor nodes 114 to the data gateway 900 through the signal amplifier 120. The tower hub 112 synchronizes data received from the sensor nodes 114 for further processing, such as determining a damping efficiency along the transmission line 104. As such, the remote computer 130 receives the synchronized sensor data from the data gateway 900 and indicates the synchronized sensor data to a user.

Referring back to FIG. 9, the data gateway 900 includes the RF I/O interface 212, the cellular I/O interface 220, and the Wi-Fi I/O interface 224, which communicate RF signals with other components of the line monitoring system 100. In this regard, the data gateway 900 receives sensor data from the sensor nodes 114 via the RF I/O interface 212, receives and transmits local data via the Wi-Fi I/O interface 224, and receives and transmits remote data with the server 124 or the remote computer 130 via the satellite I/O interface 232. As such, the data gateway 900 wirelessly transmits the sensor data from the sensor nodes 114 to the remote computer 130.

The satellite I/O interface 232 communicating with the server 124 or the remote computer 130 operates on a lower radiofrequency than the RF I/O interface 212 and the Wi-Fi I/O interface 224 communicating with the sensor nodes 114 or the signal amplifiers 120. As such, a wireless transmission range of the data gateway 900 may be greater than a wireless transmission range of the sensor nodes 114, while rates of data transfer between the sensor nodes 114 and the data gateway may be greater than a rate of data transfer between the data gateway 900 and the server 124 or the remote computer 130.

In this manner, the line monitoring system 100 provides centralized, networked communication between the sensor nodes 114 and the remote computer 130. Also, with this construction, the sensor nodes 114 do not individually require long range RF communication hardware to communicate with the remote computer 130, and are relatively light in weight. As such, each the sensor nodes 114 respectively imparts less weight onto the transmission line 104, reducing an overall amount of stress put on the transmission line 104 and increasing a number of the sensor nodes 114 that may be mounted on the transmission line 104 at a same time.

The power unit 240 includes a solar panel 902 operatively connected to the weather station 122 and the data gateway 900. The solar panel 902 is angled to optimize sunlight received from a mounted position on the transmission tower 110. The solar panel 902 generates operational electrical power used to actuate the weather station 122 and the data gateway 900.

FIG. 10 depicts one of the sensor nodes 114 according to another exemplary embodiment. As depicted in FIG. 10, the housing 300 is formed from machined anodized aluminum that rigidly holds the contains the sensor controller 304, the sensing instruments 310, the power unit 312, the internal temperature probe 314, the RF transceiver 320, the RF antenna 322, and the main instrument 324 from an external environment.

The coupler 302 is a clamp 1000 that fixes the sensor node 114 along the transmission line 104. More specifically, the clamp 1000 includes two bolts 1002 that moveably fix a jaw 1004 with a frame 1010. Rotating the bolts 1002 in a first direction drives the bolts 1002 and the jaw 1004 toward the frame 1010, clamping the transmission line 104 between the jaw 1004 and the frame 1010. In this manner, the clamp 1000 fixes the sensor node 114 with the transmission line 104.

Rotating the bolts 1002 is a second direction opposite from the first direction drives the bolts 1002 and the jaw 1004 away from the frame 1010, loosening the clamp 1000 from the transmission line 104. In this manner, the clamp 1000 and the sensor node 114 may be removed from the transmission line 104.

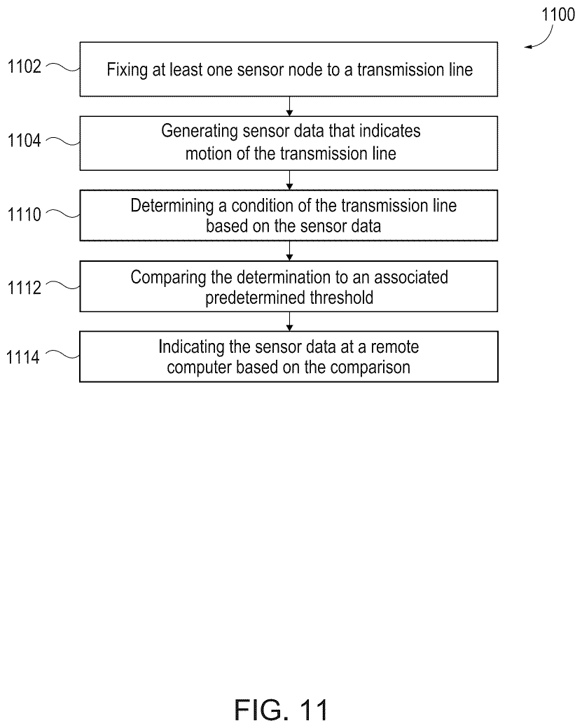

Referring to FIG. 11, a method 1100 for monitoring at least one overhead transmission line in a distribution system will be described according to an exemplary embodiment. FIG. 11 will be described with reference to FIGS. 1-10. For simplicity, the method 1100 will be described as a sequence of blocks, but the elements of the method 1100 can be organized into different architectures, elements, stages, and/or processes.

At block 1102, the method 1100 includes fixing at least one of the sensor nodes 114 to the span 604 of the transmission line 104 that extends between two of the transmission towers 110. Each of the sensor nodes 114 includes an accelerometer as the one or more instruments 310 or the main instrument 324 that detects a motion associated with the transmission line 104.

At block 1104, the method 1100 includes generating the sensor data that indicates the motion of the transmission line 104. In this regard, the plurality of sensor nodes 114 generate the sensor data with the one or more instruments 310 or the main instrument 324, and transmit the sensor data to the remote computer 130 through the signal amplifier 120, the tower hub 112, and the server 124.

At block 1110, the method 1100 includes determining a condition including the bending strain, the antinode amplitude, the damping efficiency, or the galloping amplitude of the transmission line 104 based on the sensor data from the sensor nodes 114. In this regard, the sensor nodes 114, the tower hub 112, the server 124, or the remote computer 130 determines the bending strain, the antinode amplitude, the damping efficiency, or the galloping amplitude of the transmission line 104 by processing the sensor data generated at the sensor nodes 114.

At block 1112, the method 1100 includes comparing the determination made at block 1110 to an associated predetermined threshold using a processor. In this regard, a computing element in the sensor nodes 114, the tower hub 112, the server 124, or the remote computer 130 compares the determination to an associated predetermined threshold.

At block 1114, where the determination does not meet, exceeds, or otherwise fails the predetermined threshold, the method 1100 includes indicating the sensor data at the remote computer 130 based on the comparison at block 1112 between the determination and the associated predetermined threshold. In this regard, the sensor nodes 114, the tower hub 112, the server 124, or the remote computer 130 is triggered to automatically generate the notification at the remote computer 130, where the notification is accessible to a user, as part of an automated remote alarm system monitoring the transmission line 104.

Some portions of the detailed description herein are presented in terms of algorithms and symbolic representations of operations on data bits performed by conventional computer components, including a central processing unit (CPU), memory storage devices for the CPU, and connected display devices. These algorithmic descriptions and representations are the means used by those skilled in the data processing arts to most effectively convey the substance of their work to others skilled in the art. An algorithm is generally perceived as a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be understood, however, that all of these and similar terms are to be associated with the appropriate physical quantities and are merely convenient labels applied to these quantities. Unless specifically stated otherwise, as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

As used in this application, “or” is intended to mean an inclusive “or” rather than an exclusive “or”. Further, an inclusive “or” may include any combination thereof (e.g., A, B, or any combination thereof). In addition, “a” and “an” as used in this application are generally construed to mean “one or more” unless specified otherwise or clear from context to be directed to a singular form. Additionally, at least one of A and B and/or the like generally means A or B or both A and B. Further, to the extent that “includes”, “having”, “has”, “with”, or variants thereof are used in either the detailed description or the claims, such terms are intended to be inclusive in a manner similar to the term “comprising”.

Further, unless specified otherwise, “first”, “second”, or the like are not intended to imply a temporal aspect, a spatial aspect, an ordering, etc. Rather, such terms are merely used as identifiers, names, etc. for features, elements, items, etc. For example, a first channel and a second channel generally correspond to channel A and channel B or two different or two identical channels or the same channel. Additionally, “comprising”, “comprises”, “including”, “includes”, or the like generally means comprising or including, but not limited to.

The exemplary embodiment also relates to an apparatus for performing the operations discussed herein. This apparatus may be specially constructed for the required purposes, or it may include a general-purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, and each coupled to a computer system bus.

The algorithms and displays presented herein are not inherently related to any particular computer or other apparatus. Various general-purpose systems may be used with programs in accordance with the teachings herein, or it may prove convenient to construct more specialized apparatus to perform the methods described herein. The structure for a variety of these systems is apparent from the description above. In addition, the exemplary embodiment is not described with reference to any particular programming language. It will be appreciated that a variety of programming languages may be used to implement the teachings of the exemplary embodiment as described herein.

A machine-readable medium includes any mechanism for storing or transmitting information in a form readable by a machine (e.g., a computer). For instance, a machine-readable medium includes read only memory (“ROM”); random access memory (“RAM”); magnetic disk storage media; optical storage media; flash memory devices; and electrical, optical, acoustical or other form of propagated signals (e.g., carrier waves, infrared signals, digital signals, etc.), just to mention a few examples.

The methods illustrated throughout the specification, may be implemented in a computer program product that may be executed on a computer. The computer program product may include a non-transitory computer-readable recording medium on which a control program is recorded, such as a disk, hard drive, or the like. Common forms of non-transitory computer-readable media include, for example, floppy disks, flexible disks, hard disks, magnetic tape, or any other magnetic storage medium, CD-ROM, DVD, or any other optical medium, a RAM, a PROM, an EPROM, a FLASH-EPROM, or other memory chip or cartridge, or any other tangible medium from which a computer may read and use.

Alternatively, the method may be implemented in transitory media, such as a transmittable carrier wave in which the control program is embodied as a data signal using transmission media, such as acoustic or light waves, such as those generated during radio wave and infrared data communications, and the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A line monitoring system, comprising:
a plurality of sensor nodes fixed along at least one line, wherein each of the sensor nodes includes an instrument that generates sensor data indicating a motion, rotation, position, temperature, or deformation of the line, and includes a transceiver that transmits the sensor data from the instrument;
a remote computer that indicates the sensor data to a user, wherein the sensor data from each of the sensor nodes is synchronized.

2. The system of claim 1, wherein the at least one line is a single line, each of the sensor nodes are fixed along a same span of the single line extended between two consecutive towers that support the single line, and each of the sensor nodes include an accelerometer that generates the sensor data indicating the motion of the single line along the same span.

3. The system of claim 2, wherein the plurality of sensor nodes includes a first sensor node and a second sensor node fixed between two consecutive antinodes of the single line, the first sensor node and the second sensor node generate the sensor data indicating aeolian vibration along the span of the single line, and the remote computer indicates an antinode amplitude of the line based on the sensor data.

4. The system of claim 2, wherein the plurality of sensor nodes includes a first sensor node and a second sensor node spaced from each other along the single line, the first sensor node and the second sensor node detect mechanical power flow along the single line, and the remote computer indicates a damping efficiency associated with the single line based on the detected mechanical power flow.

5. The system of claim 1, wherein the at least one line includes a first line and a second line offset from the first line in a radial direction of the first line or the second line, the plurality of sensor nodes includes a first sensor node fixed to the first line, the plurality of sensor nodes includes a second sensor node fixed to the second line, and the remote computer indicates a galloping motion of the first line or the second line based on detected motion at the first sensor node or the second sensor node.

6. The system of claim 5, wherein the first line and the second line are respectively supported between and span two consecutive towers, and
the first sensor node is fixed to a midpoint of a span of the first line, or the second sensor node is fixed to a midpoint of a span of the second line.

7. The system of claim 5, further comprising a weather station local to the first line and the second line, wherein the weather station generates environmental data indicating wind speed and direction at the first line and the second line as the sensor data, and the remote computer indicates the galloping motion of the first line or the second line based on the environmental data and the detected motion at the first sensor node or the second sensor node.

8. The system of claim 7, further comprising a tower hub fixed to a tower that supports the first line or the second line, wherein the tower hub includes the weather station and synchronizes the sensor data from the plurality of sensor nodes.

9. The system of claim 1, wherein the line is an overhead transmission line in a power distribution system.

10. A line monitoring system, comprising:
a sensor node that is fixed to a line, the sensor node including:
an instrument that generates sensor data indicating a condition of the line; and
a transceiver that transmits the sensor data from the instrument;
a tower hub that is fixed to a tower supporting the line, the tower hub including:
a data gateway that receives the sensor data from the transceiver, and transmits the sensor data; and
a remote computer that receives the sensor data from the data gateway, and indicates the sensor data to a user.

11. The line monitoring system of claim 10, wherein the transceiver wirelessly transmits the sensor data to the data gateway, the data gateway wirelessly transmits the sensor data to the remote computer, and a wireless transmission range of the data gateway is greater than a wireless transmission range of the transceiver.

12. The line monitoring system of claim 11, further comprising a signal amplifier fixed to the line at a location between the sensor node and the tower hub in a longitudinal direction of the line, wherein the transceiver wirelessly transmits the sensor data to the data gateway through the signal amplifier.

13. The line monitoring system of claim 10, wherein the tower hub includes a first interface that receives the sensor data from the sensor node, and includes a second interface that transmits the sensor data to the remote computer, wherein the second interface operates on a lower radiofrequency than the first interface.

14. The system of claim 10, further comprising a power unit included in the sensor node and operatively connected to the instrument and the transceiver, the power unit including:
a battery that stores energy on an electrical circuit connected to the instrument or the transceiver;
an energy generation device that is a solar panel or a wind turbine operatively connected to the electrical circuit; or
an energy harvesting device that draws electricity from the line to the electrical circuit.

15. The system of claim 10, further comprising a weather station included in the tower hub, wherein the weather station generates sensor data indicating environmental conditions, and the data gateway transmits the sensor data from the weather station to the remote computer.

16. The system of claim 15, further comprising a power unit included in the tower hub and operatively connected to the data gateway or the weather station, the power unit including:
a battery that stores energy on an electrical circuit connected to the data gateway or the weather station; or
a power generation device that is a solar panel or a wind turbine operatively connected to the electrical circuit.

17. The system of claim 10, wherein the instrument includes a strain gauge fixed to the line, at a location along the line where the tower supports the line,
the strain gauge generates the sensor data indicating a bending strain in the line when the line vibrates, and
the remote computer indicates an amplitude of aeolian vibration in the line based on a relationship between bending strain and an actual vibration amplitude of the line.

18. The system of claim 10, wherein the instrument includes an internal temperature probe that generates the sensor data indicating a conductor temperature of the line, or
the instrument or the tower hub includes a thermometer that generates the sensor data indicating an air temperature, and
the remote computer indicates the conductor temperature, the air temperature, or an amount of thermal cycling in the line based on the sensor data.

19. The system of claim 10, wherein at least one of the sensor node, the tower hub, and the remote computer is triggered to automatically generate a notification at the remote computer indicating the sensor data when the condition of the line fails a predetermined threshold.

20. A method of monitoring at least one overhead transmission line in a distribution system, the method comprising:
fixing at least one sensor node to a span of the at least one overhead transmission line that extends between two transmission towers, wherein each of the at least one sensor node includes an accelerometer that detects a motion associated with the at least one overhead transmission line, and generates sensor data that indicates the motion;
determining a bending strain, an antinode amplitude, a damping efficiency, or a galloping amplitude of the at least one overhead transmission line based on the sensor data,
comparing the determination to an associated predetermined threshold; and
indicating the sensor data at a remote computer based on the comparison between the determination and the associated predetermined threshold.
